(19) United States
(12) Patent Application Publication
(10) Pub. No.: US 2004/0043618 A1
(43) Pub. Date: Mar. 4, 2004

(54) Method for endpoint detection during etch

(75) Inventors: Kay Hellig, Dresden (DE); Massud Aminpur, Dresden (DE)

Correspondence Address: SIMON, GALASSO & FRANTZ PLC, P.O. BOX 26503, AUSTIN, TX, 78755-0503, US

(73) Assignee: Advanced Micro Devices, Inc.

(21) Appl. No.: 10/229,496

(22) Filed: Aug. 28, 2002

(51) Int. Cl. H01L 21/311

(52) U.S. Cl. 438/694

(57) ABSTRACT

A method is presented to increase, by means of dummy via or contact structures, the open areas to 5% or more of the total wafer area in a semiconductor manufacturing process, e.g., contact/via etch processes for interconnect layers. An open area of 5% or more allows robust endpoint detection using optical emission from the plasma, or electrical signals from the RF system. An end-pointed via/contact etch process overcomes the problems encountered due to the effects of aspect-ratio dependent etching, etch rate differences between tools, etch rate fluctuations over time, and deviations of mean incoming film thickness. With end-pointed etching, only the sources of non-uniformity over the wafer have to be considered during etch, which reduces the amount of over-etch built into a conventional via/contact etch process. The dummy structures may be redundant (functional) structures or “true” dummy (non-functional) structures. The dummy structures have the same size as functional structures.

### FIELD OF THE DISCLOSURE

The present invention relates generally to a semiconductor manufacturing process, and more particularly to a method for enhancing endpoint detection during an etch process.

### BACKGROUND

The interconnect in semiconductor chips consists of several layers of metal, connecting vias, and contacts. In order for a chip to achieve full functionality, the contacts and vias, which typically number into the millions, must be properly formed on the chip. Because proper formation of contacts and vias is so important, it is desirable to have a technique to enable precise control of the via/etch process. Optical emission spectroscopy (OES) offers precise endpoint for various etch processes, however OES has a limitation which makes the technique unsuitable for endpoint determination in conventional contact/via etch processes.

This limitation arises because there is too small a quantity change in the plasma properties when the areas being etched form only a small fraction of the total surface area of the wafer. Optical emission is unable to distinguish a small intensity change of a characteristic wavelength from the very large background signals created by the reacting plasma when the open (oxide) area for a via/contact etch is too small. Unfortunately, most contact and via layers have only very small open areas, typically on the order of between 0.5% and 2% of the total wafer surface area, which provides too small a shift in the endpoint signal to reliably distinguish the endpoint signal from background noise. Because of this limitation, most via/contact etch processes necessarily include a significant over-etch. This over-etch must take into account the aforementioned factors affecting the optical emission endpoint capabilities in order to insure the proper amount of time is applied to clear all vias/contacts.

In addition to the amount of open area, optical emission endpoint capabilities depend upon the etch application and the process chemistry employed, deviations in film thickness, etch rate differences between etching tools, as well as the effect of aspect-ratio dependant etching (ARDE) and varying critical dimension of the resist features (mean and range).

Sub-0.25 micrometer technologies commonly use un-landed or borderless contacts or vias, as seen in FIG. 1, which illustrates a cross-sectional view of a portion 100 of an interconnect layout for a semiconductor device according to the prior art. Portion 100 consists of a landed via 10, and an un-landed or borderless via 12. The term borderless means that the interconnect layout does not provide for metal lines 15 in dielectric layer 9 to be overhanging the contacts or vias. If overlay offsets occur, the via lands only partially on the underlying metal line 15, as is shown by un-landed via 12. A long via over-etch process may etch a deep and narrow “fang” 17 adjacent to the metal line 15. The fang 17 is considerably more difficult to fill with the barrier layer (not shown) and the via material, e.g., W or Cu. In order to keep fang 17 shallow, the overetch should be kept short. However, due to the previously discussed variations in factors, i.e., deviations in film thickness, etch rate differences, et cetera, the over-etch needs to be reasonably long.

In copper damascene technology, it is common to use an etch-stop layer (ESL) for the via etch. This ESL could be, for example, silicon nitride or silicon carbide. The interlevel dielectric 19, e.g., an oxide or low-k material, would be etched in a first step, stopping on an ESL 27, as seen in FIG. 2. FIG. 2 illustrates a cross-sectional view of a portion 200 of an interconnect layout for a semiconductor device according to the prior art. After stopping on ESL 27, then the resist mask (not shown) can be stripped. The copper in metal layer 25 is protected from the oxygen plasma during the etch/strip by ESL 27. Without ESL 27, any exposed copper metal 25 would be heavily oxidized, which is undesirable due to attendant high electrical resistance. In a subsequent fabrication step, the ESL 27 is opened using an etch process that is selective to dielectric layer 19, and which does not require a resist mask.

With the integration shown in FIG. 2, the first part of the via 20, 22 etch must stop on the ESL 27. For the same reasons previously discussed, however, the etch process must also include substantial over-etch. However, because the selectivity of the etch process to the ESL 27 is limited, a longer over-etch requires thicker ESL film. Unfortunately, ESL 27 cannot be made as thick as desired, because the higher k-value of the ESL 27 would increase the effective k value of the whole dielectric stack, i.e., 29, 19 and 27. This is undesirable in terms of circuit performance.

Bias compensation endpoint shows potential as a method for a number of oxide etch applications, including dual damascene via, standard via, and contact to active areas.

Bias compensation has been tested on a small scale in a production facility, which utilized the method for endpoint detection in a dual damascene via etch process. These tests showed the method to be more effective than optical emission, essentially because bias compensation is effectively independent of the exposed oxide area over the range −0.01-1%. However, due to the capitol expenditures required to modify a production line to accommodate new equipment, the bias compensation technique is not yet widely employed in the semiconductor-manufacturing sector.

Therefore, a method that overcomes the problems currently encountered during a via or contact etch process by providing an effective endpoint for the via/contact etch process without extensive re-tooling is needed.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements for clarity. Other advantages, features and characteristics of the present disclosure, as well as methods, operation and functions of related elements of structure, and the combinations of parts and economies of manufacture, will become apparent upon consideration of the following description and claims with reference to the accompanying drawings, all of which form a part of the specification, wherein like reference numerals designate corresponding parts in the various figures, and wherein:

FIG. 1 illustrates a cross-sectional view of a portion of an interconnect layout for a semiconductor device, manufactured according to the prior art;

FIG. 2 illustrates a cross-sectional view of portion of an interconnect layout for a copper damascene technology semiconductor device, manufactured according to the prior art;

FIG. 3 is a flow diagram of a method for manufacturing a semiconductor device according to at least one embodiment of the present disclosure;

FIG. 4 illustrates a cross-sectional view of a portion of an interconnect layout for dummy structures for a copper damascene technology semiconductor device according to at least one embodiment of the present disclosure;

FIG. 5 illustrates a cross-sectional view of a portion of an interconnect layout for dummy structures according to at least one embodiment of the present disclosure; and

FIGS. 6 illustrates a plan or top view of a “most dense” via layout scheme according to at least one embodiment of the present disclosure.

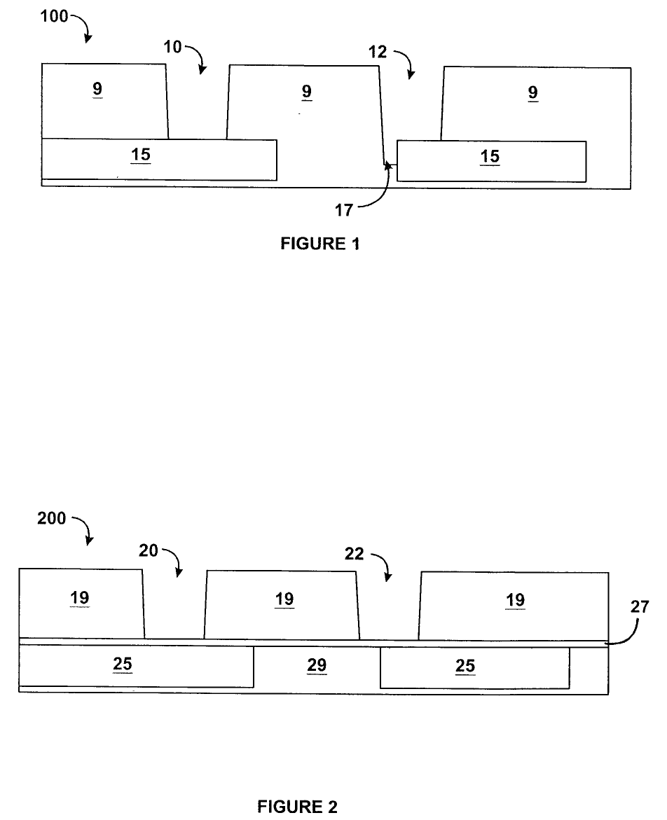

### DETAILED DESCRIPTION OF THE FIGURES

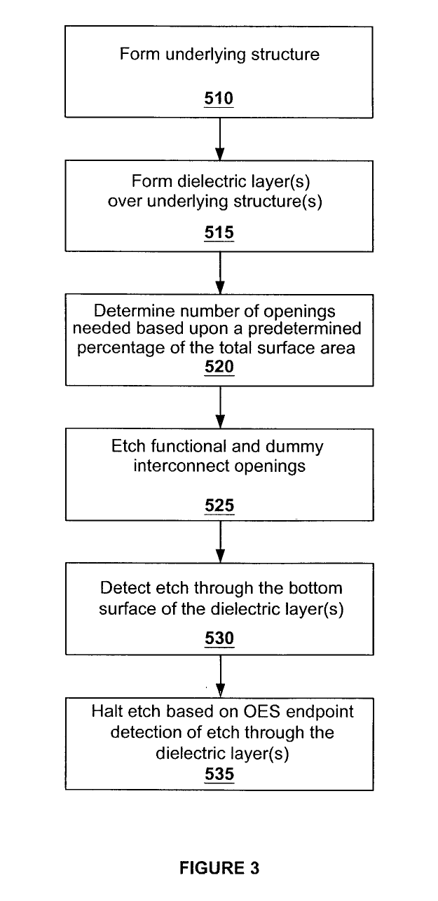

The present disclosure presents a method to increase, by means of dummy via or contact structures, the open areas to 5% or more of the total wafer area in a semiconductor device manufacturing process, e.g., contact and via etch processes for interconnect layers. This method is illustrated in FIGS. 3 through 6. In the various embodiments, having an open area of 5% or more allows robust endpoint detection using optical emission from the plasma, or electrical signals from the RF system. An end-pointed via/contact etch process overcomes the problems of the effect of aspect-ratio dependent etching (ARDE) with varying resist mean CD, the etch rate differences between tools, etch rate fluctuations over time, and deviations of mean incoming film thickness. With an end-pointed etch, only the sources of non-uniformity over the wafer have to be considered during etch, thus considerably reducing the amount of over-etch built into the conventional via/contact etch process.

In the various embodiments, the dummy structures (vias and/or contacts) may be redundant (functional) structures or “true” dummies, i.e., non-functional structures. The dummy structures have the same diameter (size) as regular (functional) vias or contacts. The dummy vias/contacts as disclosed herein can have a conductive or a non-conductive underlayer, as well as a conductive or non-conductive overlying layer, or any combination thereof. For example, in an embodiment, the dummy vias/contacts may have a conductive underlayer and a conductive overlying layer, while the vias/contacts in other embodiments may have a conductive underlayer and a non-conductive overlying layer, a non-conductive underlayer and a conductive overlying layer, or a non-conductive underlayer and a non-conductive overlying layer. The dummy structures (contacts or vias) as disclosed herein may be employed in various patterns during the interconnect phase of device manufacture. The term “interconnect openings” as used herein includes openings between metal layers, as well as openings between metal layers and active silicon. The terms “interconnect structure” or “interconnect region” as used herein includes vias and contacts.

An embodiment of the method comprises providing a semiconductor substrate over which a first interconnect layer is formed. Active and dummy metal interconnect regions are formed in the first interconnect layer, and then a first dielectric layer is formed overlying the first interconnect layer. Interconnect openings and dummy interconnect openings are formed in the first dielectric layer. Interconnect openings reach the underlying active metal interconnect regions. Active and dummy first metal regions are then formed overlying the interconnect openings, and a second dielectric layer is formed overlying the active and dummy first metal regions which overlie the interconnect openings. Interconnect openings and dummy interconnect openings are formed in the second dielectric layer. These interconnect openings reach the active and dummy first metal regions which overlie the interconnect openings. A third level metal interconnect layer is then formed overlying the second dielectric layer. This process can be repeated until the desired number of levels of metal interconnects have been formed, at which time a passivation layer is deposited overlying the final-level metal interconnect layer. In an embodiment, the active metal interconnect regions are contacts, and the interconnect openings are vias. The present disclosure may be applied to conventional “subtractive” aluminum technology, as well as copper (damascene) technology.

The semiconductor substrate has a total surface area, and the quantity of dummy interconnect openings is based upon the quantity of interconnect openings (via holes) and the total surface area. In an embodiment, the quantity of dummy interconnect openings and the quantity of interconnect openings are based upon at least a predetermined percentage of the total surface area, i.e., at least about 5%. The predetermined percentage is based on sensitivity of optical emission endpoint, that is, the minimal required OES signal change to reliably detect endpoint in a manufacturing environment.

The steps taken to practice the teachings disclosed herein are presented in FIG. 3, a flow diagram of a method for fabricating a device on a semiconductor wafer according to an embodiment of the present disclosure, is discussed. In step 510, an underlying structure, or underlayer as it is referred to in the art, is formed. The underlayer may be formed over transistors in the device, in the case of contacts, or the underlayer may be formed over a metal interconnect layer, in the case of vias. In an embodiment, the underlayer is a conductive material, although the underlayer can be a non-conductive material in another embodiment. The choice of conductive or non-conductive underlayer as formed in step 510 would be determined by the particular requirements of the device technology applied during fabrication. For example, in the case of contacts, the possible underlayers are metal suicides, e.g., WSi, TiSi, CoSi, NiSi, or silicon. For vias, possible underlayers are Cu (in copper damascene technology, Al (in Al technology), oxides from precursors such as TEOS, or fluorinated oxides such as fluorinated silicon glass (FSG), or low-k dielectric materials such as Applied Materials Black Diamond, Novellus' Coral, or Dow's SiLK. In an embodiment, an etch stop layer (ESL) may be formed over the underlayer if desired. When copper damascene technology is used and an ESL is needed, the ESL would typically consist of a thin, non-conductive dielectric layer, e.g., silicon nitride or silicon carbide.

In step 515 a dielectric layer having a top surface and a bottom surface is formed over the underlayer, or over the dielectric etch stop layer (ESL) formed over the underlayer, if an ESL is utilized. The bottom surface of the dielectric layer is nearer the underlying structure than the top surface. This overlying dielectric layer should be an insulative or a non-conductive material such as Black Diamond, FSG, Coral, SiLK, or oxide from precursors such as TEOS, as determined by device technology requirements.

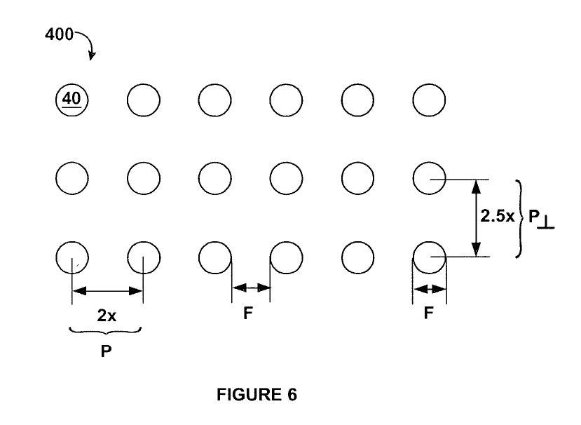

Prior to fabrication of the mask (reticle) for the via/contact etch process, in step 520 a determination of the total number of dummy interconnect openings (vias or contacts) required to obtain a predetermined value, expressed as a percentage of the total surface area to be etched, is made in accordance with any design rule(s) in effect during the fabrication cycle. In an embodiment, the predetermined percentage is at least about 5% of the total wafer area, and is based on the sensitivity of emission endpoint. The quantity of second (dummy) interconnect openings required to obtain the predetermined value, e.g., 5% or greater, if a “most dense” scheme (FIG. 6) is applied, is based upon the quantity of first (functional) interconnect openings and the total surface area of the semiconductor wafer. For example, if the number of dummy structures needed is greater than or equal to 5%, the following equation could be used to determine the quantity of dummy interconnect openings required as follows:

{[(5%/100%)×(Total wafer area/Area of one interconnect opening)]−(Number of first (functional) interconnect openings)}.

After the determination in step 520, the mask (reticle) is fabricated and applied to the wafer. The mask is used to form the dummy and active openings, and, once applied, the via/contact etching process is ready to begin. In step 525, a plurality of first interconnect openings (functional structures) are etched, and, simultaneously, a plurality of second interconnect openings are etched. The plurality of second interconnect openings are dummy openings, i.e., non-functional structures, however they have the same size as their counterpart functional structures (vias or contacts).

The etching process is monitored during etch by means of optical emission spectroscopy (OES). When at least about 5% of the total wafer area is opened as taught herein, the OES measurement possesses the minimal required change of signal during etch to make the OES endpoint technique quite reliable in a production/manufacturing environment. Thus step 530, detection of when etching through the bottom surface of the dielectric layer has occurred, is by means of OES endpoint. Should an etch stop layer be utilized, the first part of the via/contact etch process would stop on the ESL, with OES endpoint being used as well, since the ESL, although a dielectric, is a different dielectric material from that of the main dielectric layer. The second part of the via/contact etch process would then continue through the ESL into the underlying structure formed in step 510. The etch process through the ESL may also be monitored by OES endpoint if at least 5% of the total area is opened as disclosed herein. In step 535, the etch process is halted based upon detection of the etch through the dielectric layer.

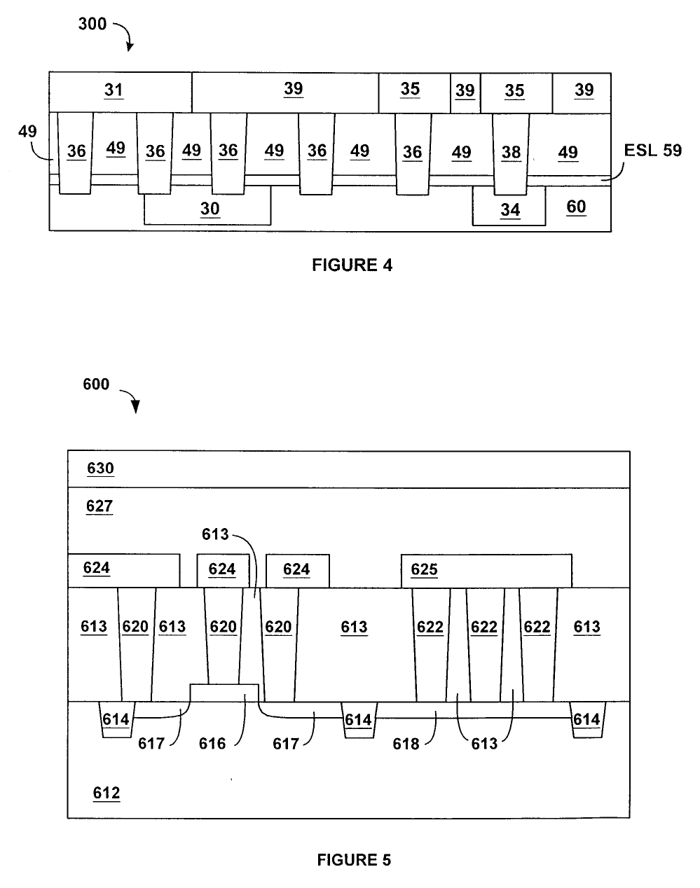

An example of some possible placements of dummy structures is shown in FIG. 4, which illustrates a cross-sectional view of a portion 300 of a possible interconnect layout for dummy structures for a copper damascene technology semiconductor device according to the present disclosure. The portion 300 of interconnect layout shows metal layer dummy structures 30 and 31, which were formed along with the first metal interconnect structures 34 and 35 within dielectric layer 60 and dielectric layer 39 respectively. Layer 59 serves as an etch stop layer during the first part of the via etch process, as is well known in the art. The semiconductor device, of which FIG. 4 illustrates only a portion (300), is comprised of a plurality of transistors required to implement desired functions of the semiconductor device. The transistors, however, are not shown in FIG. 4 in order to keep FIG. 4 straightforward.

Metal interconnect structure 34 and metal layer dummy structure 30 comprise a first patterned conductive structure overlying the plurality of transistors. The first patterned conductive structure contains a first patterned portion (metal interconnect structure 34) and a second patterned portion (metal dummy structure 30). Members of the first patterned conductive structure that are connected to at least one of the plurality of transistors (not shown) comprise the first patterned portion (metal interconnect structure 34) and members of the first patterned conductive structure that are physically isolated from the first patterned portion comprise the second patterned portion (metal dummy structure 30). An insulative layer (dielectric) 49 overlies the first patterned conductive structure (30, 34), and a first plurality of conductive structures 38 surrounded by the insulative layer 49 and connected to at least one member of the first patterned portion (30, 34). The first plurality of conductive structures 38 have a first cross-sectional surface area, relative to an upper surface of the insulative layer 49.

A second plurality of conductive structures 31 and 35, is surrounded by insulative layer 39, and is connected to at least one member of the first patterned portion 30, 34. The second plurality of conductive structures 36 has a second cross-sectional surface area relative to the upper surface of insulative layer 49. In an embodiment, the cross sectional area represented by the sum of the first and second cross sectional surface areas is greater than 5%. In another embodiment, the cross sectional area is greater than 2%. Alternately, the cross sectional area of the second plurality of conductive structures is greater than 2%. The 5% value allows robust endpoint detection in almost all processes, etch tools, and settings. The 2% value also allows enhanced endpoint detection, although the use of 2% will generally required a higher sensitivity OES system, and may depend on the process. It should be noted that numerous possibilities exist for dummy structure placement schemes, and that the layout presented in FIG. 4 serves as but one example from many possible placement schemes (layouts).

FIG. 5, which illustrates a cross-sectional view of a portion 500 of an interconnect layout for dummy structures according to an embodiment of the present disclosure, is presented. Portion 500 comprises a substrate 612, isolation regions 614, a gate structure 616, source/drain regions 617, and diffusion region 618. Functional structures 620 and dummy (non-functional) structures 622 have been formed in a first insulative (dielectric) layer 613 in accordance with the teachings disclosed herein. Functional structures 620 connect to the gate structure 616 and the source/drain regions 617, while dummy structures 622 connect to the diffusion region 618. An interconnect metal layer is deposited, and active 624 and dummy 625 metal regions formed therein. Other layers 627, which would include at least a dielectric layer, are then formed overlying the second interconnect metal layer structures 624 and 625. In an embodiment, the active metal interconnect regions 624 are contacts. This process would continue until the desired number of interconnect levels has been reached, after which time a passivation layer 630 would be formed over the final level. Only one level is illustrated in FIG. 6 to avoid unnecessary detail, although the teachings herein can be applied to form as many interconnect levels as desired.

The teachings herein direct the use of as many dummy vias/contacts as possible, or providing for as dense an array of dummy structures as allowed by the technology, i.e., no inadvertent shorting of metal or polysilicon or active areas. Providing as many dummy structures as possible can provide more than a 5% open area for an area having dummy structures in a dense array. Such a “most dense” via layout is shown in FIG. 6.

FIG. 6 illustrates a plan or top view of a portion of a “most dense” via layout scheme 400 with an open area greater than 5%, created according to an embodiment of the present disclosure. The layout scheme of FIG. 6 is dependent on the design rules/process used. The circles in layout scheme 400 represent via structures 40. Via structures 40 may be only dummy structures, or may be a mixture of dummy and functional structures, according to need and design rules. Distance F indicates the size (diameter) of the structures 40, as well as the distance in one direction, e.g., horizontally, separating structures 40. With the minimum pitch in one direction being 2×feature size F, and the pitch P1 in the perpendicular direction being 2.5×feature size F, dummy structures with diameter F will provide about 15% open area for the area having these dummy structures in a most dense array. Applying these teachings to a conventional via layout with the assumption of an open area of 1% (a typical via layout scheme) means that it would be sufficient to place dummy structures on about 1/4 of the chip area in order to achieve a 5% total open area. The 5%+total open area as described herein enables the minimal required optical emission spectroscopy signal change to reliably detect endpoint in a manufacturing environment. It should be noted that although FIG. 6 illustrates an approximation of the schema used for AMD/Motorola HiP8 design rules, the teachings of the present disclosure can be applied to different design rules, and would provide the same advantages when applied to other design rules known in the art.

The method and apparatus herein provides for a flexible implementation. Although the invention has been described using certain specific examples, it will be apparent to those skilled in the art that the invention is not limited to these few examples. For example, the disclosure is discussed herein primarily with regard to dummy structure formation for contact and via etching processes for interconnect layers in copper damascene technology device, however, the invention can be employed with other device technologies to create dummy structures by etching processes during device manufacture. Additionally, various types of deposition and etch devices are currently available which could be suitable for use in employing the method as taught herein. Note also, that although an embodiment of the present invention has been shown and described in detail herein, along with certain variants thereof, many other varied embodiments that incorporate the teachings of the invention may be easily constructed by those skilled in the art. Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. Accordingly, the present invention is not intended to be limited to the specific form set forth herein, but on the contrary, it is intended to cover such alternatives, modifications, and equivalents, as can be reasonably included within the spirit and scope of the invention.

What is claimed is:

1. A method for fabricating a device on a semiconductor wafer comprising:
forming an underlying structure;
forming a dielectric layer overlying the underlying structure, the dielectric layer having a top surface and a bottom surface, where the bottom surface is nearer the underlying structure than the top surface;
etching a plurality of first interconnect openings in the dielectric layer;
etching a plurality of second interconnect openings in the dielectric layer, wherein the second interconnect openings are dummy interconnect openings and are etched simultaneously with the first interconnect openings;
detecting when the first and second interconnect openings are etched through the bottom surface of the dielectric layer; and
halting the etching process based upon detection of the etch through the dielectric layer.

2. The method of claim 1, wherein the underlying structure is a conductive layer.

3. The method of claim 1, wherein the underlying structure is an active area.

4. The method of claim 1, wherein the first and second pluralities of interconnect openings are via openings.

5. The method of claim 1, wherein the first and second pluralities of interconnect openings are contact openings.

6. The method of claim 1, wherein the semiconductor wafer has a total surface area, and wherein a quantity of the second interconnect openings is based upon a quantity of the first interconnect openings and the total surface area.

7. The method of claim 6, wherein the quantity of second interconnect openings and the quantity of the first interconnect openings are based upon at least a predetermined percentage of the total surface area.

8. The method of claim 7, wherein the predetermined percentage is at least 2% of the total surface area.

9. The method of claim 7, wherein the predetermined percentage is at least 5% of the total surface area.

10. The method of claim 7, wherein the predetermined percentage is based on sensitivity of optical emission endpoint.

11. The method of claim 7, wherein the predetermined percentage is based on a minimal required optical emission spectroscopy signal change to reliably detect endpoint in a manufacturing environment.

12. The method of claim 1, further comprising the steps of:
forming an overlying conductive layer abutting the first plurality of interconnect openings; and
forming a non-conductive layer abutting the second plurality of interconnect openings.

13. The method of claim 1, further comprising the steps of:
forming a first portion of an overlying conductive layer abutting the first plurality of interconnect openings; and
forming a second portion of the overlying conductive layer abutting the second plurality of interconnect openings.

14. The method of claim 13, further comprising forming metal in at least one of the second plurality of interconnect openings.

15. A semiconductor device comprising:
a plurality of transistors to implement a desired function of the semiconductor device;
a first patterned conductive structure overlying the plurality of transistors, the first patterned conductive structure comprising a first patterned portion and a second patterned portion, where members of the first patterned conductive structure that are connected to at least one of the plurality of transistors comprise the first patterned portion and members of the first patterned conductive structure that are physically isolated from the first patterned portion comprise the second patterned portion;
an insulative layer overlying the first patterned conductive structure;
a first plurality of conductive structures surrounded by the insulative layer connected to at least one member of the first patterned portion, wherein the first plurality of conductive structures have a first cross-sectional surface area, relative to an upper surface of the insulative layer;
a second plurality of conductive structures surrounded by the insulative layer connected to at least one member of the first patterned portion, wherein the second plurality of conductive structures have a second cross-sectional surface area, relative to the upper surface; wherein
the cross sectional area represented by the sum of the first and second cross sectional surface areas is greater than 5%.

16. The method of claim 15, wherein the cross sectional area is greater than 2%.

17. The method of claim 15, wherein the cross sectional area of the second plurality of conductive structures is greater than 2%.

18. A method comprising the steps of:
providing a semiconductor substrate;
forming active and dummy metal interconnect regions in a first interconnect layer;
forming a first dielectric layer overlying the first interconnect layer;
forming interconnect openings and dummy interconnect openings in the first dielectric layer, wherein the interconnect openings reach the underlying active metal interconnect regions;
forming active and dummy first metal regions overlying the interconnect openings;
forming a second dielectric layer overlying the active and dummy first metal regions overlying the interconnect openings;
forming interconnect openings and dummy interconnect openings in the second dielectric layer, wherein the interconnect openings reach the active and dummy first metal regions overlying the interconnect openings;
forming a third level metal interconnect layer overlying the second dielectric layer; and
depositing a passivation layer overlying the third level metal interconnect layer.

19. The method of claim 18, wherein the active metal interconnect regions are contacts.

20. The method of claim 18, wherein the interconnect openings are vias.

21. The method of claim 18, wherein the semiconductor substrate has a total surface area, and wherein a quantity of dummy interconnect openings is based upon a quantity of interconnect openings and the total surface area.

22. The method of claim 21, wherein the quantity of dummy interconnect openings and the quantity of the interconnect openings are based upon at least a predetermined percentage of the total surface area.

23. The method of claim 21, wherein the predetermined percentage is at least 5% of the total surface area.

24. The method of claim 21, wherein the predetermined percentage is based on sensitivity of optical emission endpoint.

25. The method of claim 24, wherein the predetermined percentage is based on a minimal required optical emission spectroscopy signal change to reliably detect endpoint in a manufacturing environment.
